(19) United States
(12) Patent Application Publication
(10) Pub. No.: US 2025/0316601 A1
(43) Pub. Date: Oct. 9, 2025

(54) PACKAGE STRUCTURE, FABRICATION METHOD THEREOF, AND SEMICONDUCTOR STRUCTURE

(71) Applicant: Yangtze Memory Technologies Co., Ltd., Wuhan (CN)

(72) Inventor: Peng SUN, Wuhan (CN)

(21) Appl. No.: 18/885,478

(22) Filed: Sep. 13, 2024

(30) Foreign Application Priority Data
Apr. 9, 2024 (CN) 202410424379.2

(51) Int. Cl. H01L 23/538; H01L 23/00; H01L 23/14; H01L 23/48; H01L 25/00; H01L 25/065; H10B 80/00

(52) U.S. Cl. CPC H01L 23/5385; H01L 23/147; H01L 23/481; H01L 24/08; H01L 25/0657; H01L 25/50; H01L 2224/08225; H01L 2225/06572; H10B 80/00

(57) ABSTRACT

Examples of the present application provide a package structure, a fabrication method thereof, and a semiconductor structure. The package structure includes a first insulation layer, a first die, a second insulation layer and a second die in sequence along a first direction, wherein the package structure further includes: a first filling structure extending through the first insulation layer along the first direction; a first contact structure extending through the first insulation layer along the first direction; and a second contact structure extending through the first filling structure, the first die and the second insulation layer along the first direction.

### CROSS-REFERENCE TO RELATED APPLICATIONS

This application claims priority to Chinese Patent Application No. 202410424379.2, filed on Apr. 9, 2024, which is hereby incorporated by reference in its entirety.

### TECHNICAL FIELD

The present application relates to the field of semiconductor technology, and more particularly to a package structure, a fabrication method thereof, and a semiconductor structure.

### BACKGROUND

Driven by demands such as miniaturization and higher integration level, etc., advanced packaging has emerged. The advanced packaging has opened up a new route for development of integrated circuit, and can improve performance of a chip by improving packaging methods without shrinking the process node.

### SUMMARY

The present application provides a package structure, a fabrication method of the package structure and a semiconductor structure that can at least partially solve the above-mentioned problem or other problems in the field.

In a first aspect, some examples of the present application provide a package structure. The package structure comprises a first insulation layer, a first die, a second insulation layer and a second die in sequence along a first direction, and further comprises: a first filling structure extending through the first insulation layer along the first direction; a first contact structure extending through the first insulation layer along the first direction; and a second contact structure extending through the first filling structure, the first die and the second insulation layer along the first direction.

In an example implementation, the package structure further comprises: a first routing layer between the first insulation layer and the first die; and a second routing layer between the second insulation layer and the second die, wherein the first filling structure extends into the first routing layer.

In an example implementation, the first routing layer and the second routing layer both comprise an insulation material layer, and at least one layer of via structure and at least one layer of interconnection line that are located in the insulation material layer.

In an example implementation, the package structure further comprises: a second filling structure extending through the second insulation layer along the first direction and extending into the second routing layer.

In an example implementation, materials of the first filling structure and the second filling structure both comprise silicon.

In an example implementation, a sidewall of the first filling structure has a spacing distance from a sidewall of the second filling structure in a second direction, wherein the second direction intersects the first direction.

In an example implementation, the first routing layer is in contact with the first insulation layer and the first die separately, and the first insulation layer, the first routing layer and the first die serve as a first semiconductor structure; the second routing layer is in contact with the second insulation layer and the second die separately, and the second insulation layer, the second routing layer and the second die serve as a second semiconductor structure, wherein the second semiconductor structure is connected with the first semiconductor structure by bonding.

In an example implementation, on a side of the second die facing away from the first insulation layer, the package structure further comprises a third insulation layer, a third routing layer and a third die in sequence along the first direction.

In an example implementation, the third routing layer is in contact with the third insulation layer and the third die separately, and the third insulation layer, the third routing layer and the third die serve as a third semiconductor structure connected with the second semiconductor structure by bonding, wherein at least one of the third semiconductor structures is arranged along the first direction, and adjacent ones of the third semiconductor structures are connected by bonding.

In an example implementation, a first dielectric layer is located on a sidewall of the first filling structure, wherein the first filling structure is in contact with the first die.

In an example implementation, a first dielectric layer is located on a sidewall of the first filling structure and on a surface of the first filling structure facing the first die and is in contact with the first die.

In an example implementation, the first die is further in contact with the second insulation layer.

In an example implementation, in a plane perpendicular to the first direction, a size of the first contact structure is 50-300 nm, and a size of the second contact structure is 50-300 nm.

In an example implementation, in the plane perpendicular to the first direction, a size of the first contact structure is smaller than a size of the second contact structure.

In an example implementation, the first filling structure is located at a middle portion of the first insulation layer or located at a periphery of the first insulation layer.

In an example implementation, the first die comprises a memory array structure and a peripheral circuit structure along the first direction, and the memory array structure and the peripheral circuit structure are connected by bonding.

In a second aspect, some examples of the present application provide a semiconductor structure. The semiconductor structure comprises: a first die; a first routing layer on a surface of the first die; a first insulation layer on a surface of the first routing layer; and a first contact structure extending through the first insulation layer until reaching the first routing layer.

In an example implementation, a surface of the first die facing the first routing layer has a plurality of first pad structures; and the first routing layer comprises a first insulation material layer, and at least one layer of first via structure and at least one layer of first interconnection line that are located in the first insulation material layer, wherein the first pad structures are in contact with the first via structure, and the first contact structure is in contact with the first interconnection line.

In an example implementation, the first contact structure comprises a first conductive body and a first insulating isolation layer, the first conductive body is in contact with the first interconnection line, and the first insulating isolation layer surrounds an outer side of the first conductive body.

In an example implementation, materials of the first conductive body and the first interconnection line both comprise tungsten.

In a third aspect, some examples of the present application provide a fabrication method of a package structure. The fabrication method of the package structure comprises: forming a first insulation layer on a side of a first die, and forming a first filling structure extending through the first insulation layer along a first direction; forming a second insulation layer on a side of a second die; connecting the first die to a side of the second insulation layer facing away from the second die; and forming a first contact structure extending through the first insulation layer along the first direction, and forming a second contact structure extending through the first filling structure, the first die and the second insulation layer along the first direction, wherein the first direction is a stacking direction of the first die and the second die.

In an example implementation, the fabrication method further comprises: forming a first routing layer between the first die and the first insulation layer; and forming a second routing layer between the second die and the second insulation layer.

In an example implementation, forming a first filling structure extending through the first insulation layer along a first direction comprises: forming a first opening extending through the first insulation layer and the first routing layer until reaching the first die along the first direction; and forming the first filling structure in the first opening, wherein before forming the first filling structure in the first opening, the fabrication method further comprises: forming a first dielectric layer on an inner wall of the first opening.

In an example implementation, forming a first contact structure extending through the first insulation layer along the first direction and forming a second contact structure extending through the first filling structure, the first die and the second insulation layer along the first direction comprise: forming an initial second contact hole extending through the first filling structure and the first die until reaching the second insulation layer; deepening the initial second contact hole until reaching the second routing layer to form a second contact hole; forming a first contact hole extending through the first insulation layer; and forming the first contact structure and the second contact structure in the first contact hole and the second contact hole respectively.

In an example implementation, the initial second contact hole is deepened and the first contact hole is formed in a same etching process.

### BRIEF DESCRIPTION OF THE DRAWINGS

Other features, purposes and advantages of the present application will become more apparent by reading the detailed description of non-limiting examples with reference to the following drawings. In the drawings:

FIG. 1A is a perspective view of a package structure according to one example of the present application;

FIG. 1B is a schematic cross-sectional view of the package structure shown in FIG. 1A;

FIG. 2 is a schematic cross-sectional view of a package structure according to another example of the present application;

FIG. 3 is a perspective view of a package structure according to yet another example of the present application;

FIG. 4 is a schematic cross-sectional view of a package structure according to still another example of the present application;

FIG. 5 is a flow diagram of a fabrication method of a package structure provided by one example of the present application;

FIGS. 6A to 6F are schematic cross-sectional views of a package structure provided by one example of the present application during a fabrication process; and

FIGS. 7A to 7D are schematic cross-sectional views of a package structure provided by another example of the present application during a fabrication process.

### DETAILED DESCRIPTION

In order to better understand the present application, various aspects of the present application will be described in more detail with reference to the drawings. It is understood that, these detailed descriptions are only descriptions of example implementations of the present application, and are not intended to limit the scope of the present application in any manner. Like reference numbers denote like elements throughout the specification. The expression “and/or” includes any or all combinations of one or more of listed associated items.

It is to be noted that, in this specification, the expressions such as first, second, third and the like, are only used to distinguish one feature from another, instead of representing any limitation to the features, particularly instead of representing any sequence. Thus, without departing from the teaching of the present application, a first die discussed in the present application may be also called a second die, and vice versa.

For ease of illustration, the thicknesses, sizes and shapes of components have been slightly adjusted in the drawings. The drawings are merely examples and are not drawn to scale precisely. As used herein, terms “approximately”, “about”, and the like, are used to represent approximation rather than to represent the degree, and are intended to describe inherent deviations in measured values or calculated values as recognized by those of ordinary skill in the art.

It should be also understood that, expressions such as “comprise”, “comprising”, “have”, “include”, and/or “including”, etc., are open-ended expressions, rather than close-ended expressions in the specification. They represent the existence of the stated features, elements and/or components, but do not preclude the existence of one or more other features, elements, components and/or combinations thereof. Moreover, the expression such as “at least one of . . . ” appearing before a list of listed features, modifies the whole list of features, rather than an individual element therein. Furthermore, “may” is used to represent “one or more implementations of the present application” when describing the implementations of the present application. Moreover, the term “exemplary” is intended to refer to an example or illustration.

Unless otherwise defined, all phrases (including engineering terms and technical terms) as used herein have the same meanings as those generally understood by those of ordinary skill in the art to which the present application pertains. It should be further understood that, terms as defined in common dictionaries should be interpreted as having a meaning that is consistent with their meaning in the context of the related art, and should not be interpreted in an idealized or overly formal sense unless otherwise stated expressly in the present application.

It is to be noted that, implementations and features in the implementations of the present application may be combined with each other without conflict. In addition, unless otherwise defined expressly or conflicting with the context, specific operations included in a method as set forth in the present application are not necessarily limited to the described order, but may be performed in any order or in parallel.

Furthermore, “connected” or “joined”, when used in the present application, may represent direct contact or indirect contact between respective components, unless otherwise expressly defined or derived from the context.

The present application will be detailed below by reference to the figures and in conjunction with the examples.

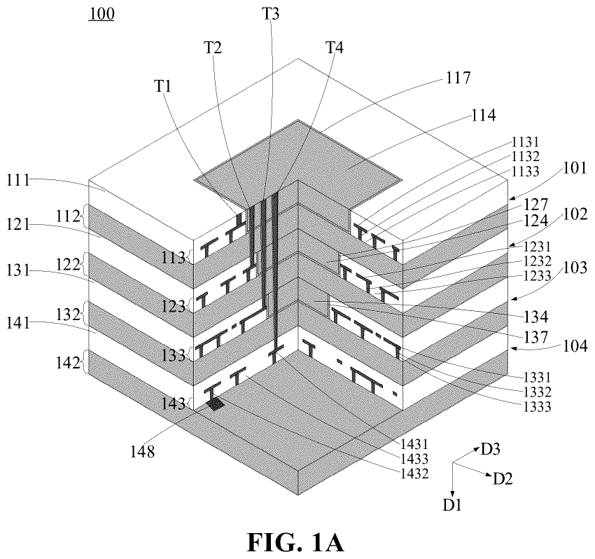

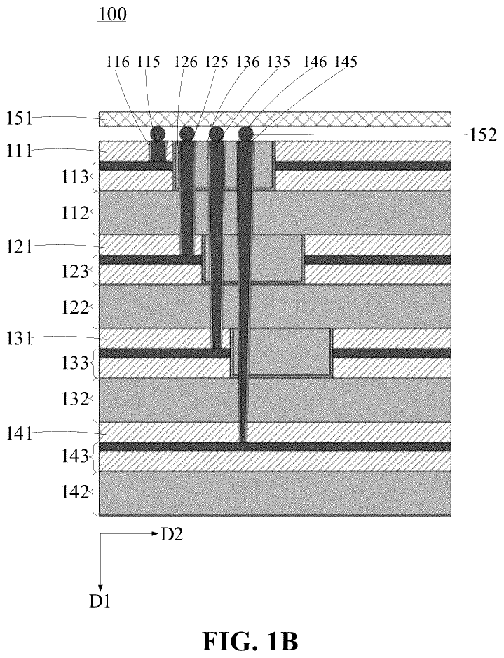

Some examples of the present application provide a package structure. FIG. 1A is a perspective view of a package structure according to one example of the present application. FIG. 1B is a schematic cross-sectional view of the package structure shown in FIG. 1A. In order to show an internal structure of the package structure 100 more clearly, part of the package structure 100 is removed in FIG. 1A to expose the internal structure of the package structure 100.

It should be noted that a direction D1, a direction D2 and a direction D3 in the drawings show a spatial relationship of each component in the package structure. For example, the direction D1 may be a stacking direction of a first die and a second die, and the direction D2 and the direction D3 may be two directions intersecting (e.g., perpendicular to) each other in a plane intersecting (e.g., perpendicular to) the stacking direction, respectively. The spatial relationship of each component in the package structure will be described with the same concept throughout the present application.

As shown in FIGS. 1A and 1B, the package structure 100 comprises a first insulation layer 111, a first die 112, a second insulation layer 121 and a second die 122 in sequence along the direction D1. The package structure 100 further comprises a first filling structure 114, a first contact structure T1 and a second contact structure T2. The first filling structure 114 extends through the first insulation layer 111 along the direction D1. The first contact structure T1 extends through the first insulation layer 111 along the direction D1. The second contact structure T2 extends through the first filling structure 114, the first die 112 and the second insulation layer 121 along the direction D1.

In the package structure 100 provided by the example of the present application, the first contact structure T1 extends through the first insulation layer 111 along the direction D1. The first die 112 is connected with an external component through the first contact structure T1. The second contact structure T2 extends through the first filling structure 114, the first die 112 and the second insulation layer 121 along the direction D1. The second die 122 is connected with an external component through the second contact structure T2. The size of the package structure 100 may be compressed in the direction D1 to increase vertical integration level. Compared with metal wiring connection or solder ball connection between dies, it can reduce conductive impedance, reduce transmission time, and increase connection density and transmission speed, thereby being conducive to follow a development trend of high bandwidth.

In some implementations, the so-called “die” in the present application may be a die that is cut from a wafer and has not been packaged. A surface of the die may have a pad structure that is configured to connect with an external component. For example, a surface of a fourth die 142 may have a fourth pad structure 148.

In some implementations, the first die 112 may be a die stack. Each single die in the die stack may be formed on the same substrate. For example, the first die 112 may be a die stack constituted by connecting a memory array structure and a peripheral circuit structure by bonding. The memory array structure and the peripheral circuit structure may be formed on different substrates respectively. The memory array structure may comprise a plurality of memory cells. For example, the memory cell may include, but is not limited to, a NAND memory cell, a NOR memory cell, a DRAM memory cell, a DRAM memory cell, a ferroelectric memory cell, a phase change memory cell, a magneto resistive memory cell, etc. The peripheral circuit structure may comprise any suitable digital, analog and/or hybrid signal peripheral circuit for controlling operations of a plurality of memory cells. For example, the peripheral circuit may comprise one or more of a page buffer, a decoder (e.g., a row decoder and a column decoder), a sense amplifier, a driver (e.g., a word line driver), an input/output (I/O) circuit, a charge pump, a voltage source or generator, a current or voltage reference, any part (e.g., a sub-circuit) of the above-mentioned functional circuits, or any active or passive components (e.g., a transistor, a diode, a resistor, or a capacitor) of the circuits.

In some other implementations, the first die 112 may be a single die that may be formed on a substrate.

In some implementations, the second die 122 may be a die stack. Each single die in the die stack may be formed on a substrate. For example, the second die 122 may be a die stack constituted by connecting a memory array structure and a peripheral circuit structure by bonding. The memory array structure and the peripheral circuit structure may be formed on different substrates, respectively. In some other implementations, the second die 122 may be a single die that may be formed on a substrate.

In some implementations, both the first die 112 and the second die 122 may be a die stack. The number of single dies that the first die 112 comprises may be the same as or may be different from the number of single dies that the second die 122 comprises, which is not limited by the present application. For example, the first die 112 and the second die 122 each may be a die stack constituted by connecting a memory array structure and a peripheral circuit structure by bonding. In some other implementations, one of the first die 112 and the second die 122 is a die stack, and the other one is a single die. In some further implementations, both the first die 112 and the second die 122 may be a single die.

It is to be noted that, in the case where at least one of the first die 112 or the second die 122 is a die stack, at least some of the substrates of at least one of the first die 112 or the second die 122 may be removed during a formation process, and therefore, the number of the substrates in at least one of the first die 112 or the second die 122 may be less than or equal to the number of the single dies.

In some implementations, a substrate material of the first die 112 may include a semiconductor material, e.g., at least one of monocrystalline silicon, polycrystalline silicon, monocrystalline germanium, a group III-V compound semiconductor material, a group II-VI compound semiconductor material, or other semiconductor materials known in the art. A substrate material of the second die 122 may include a semiconductor material, e.g., at least one of monocrystalline silicon, polycrystalline silicon, monocrystalline germanium, a group III-V compound semiconductor material, a group II-VI compound semiconductor material, or other semiconductor materials known in the art. For example, the substrate material of the first die 112 and the substrate material of the second die 122 are the same, e.g., both are silicon. For another example, the substrate material of the first die 112 and the substrate material of the second die 122 are different.

In some implementations, the first insulation layer 111 may be located on a side of the first die 112 facing away from the second die 122. For example, the first insulation layer 111 may extend laterally along the direction D2 and the direction D3. A material of the first insulation layer 111 may include one or more of silicon oxide (SiO₂), silicon nitride (Si₃N₄), silicon oxynitride (SiOₓN_{y}), or any other suitable insulation materials.

In some implementations, the second insulation layer 121 may be located on a side of the second die 122 facing the first die 112. For example, the second insulation layer 121 may extend laterally along the direction D2 and the direction D3. A material of the second insulation layer 121 may include one or more of silicon oxide (SiO₂), silicon nitride (Si₃N₄), silicon oxynitride (SiOₓN_{y}), or any other suitable insulation materials.

In some implementations, the first die 112 may be in contact with the second insulation layer 121. For example, the first die 112 and the second insulation layer 121 may be connected by any “bonding technique” known in the art. The so-called “bonding technique” in the present application may include, but is not limited to, fusion bonding, anodic bonding, eutectic bonding and hybrid bonding.

In some implementations, a material of the first filling structure 114 may include a semiconductor material, e.g., silicon. The first filling structure 114 may be located at a middle portion of the first insulation layer 111. In some examples, in a plane perpendicular to the direction D1, the first insulation layer 111 may surround the first filling structure 114. In some other examples, in the plane perpendicular to the direction D1, the first insulation layer 111 may surround a part of the first filling structure 114. The first filling structure 114 is conducive to reducing the process difficulty and manufacturing cost of forming the second contact structure T2 and increasing the yield of the package structure 100.

In some implementations, the first contact structure T1 may comprise a first conductive body 115 and a first insulating isolation layer 116. The first insulating isolation layer 116 surrounds an outer side of the first conductive body 115. For example, the first conductive body 115 may have a roughly pillar-shaped structure, and the first insulating isolation layer 116 may have a roughly tube-shaped structure with openings at both ends. The first insulating isolation layer 116 may cover a sidewall of the first conductive body 115. A material of the first conductive body 115 may include one or more of titanium (Ti), titanium nitride (TiN), tantalum (Ta), tantalum nitride (TaN), polycrystalline silicon (poly-Si), amorphous silicon (a-Si), tungsten (W), molybdenum (Mo), copper (Gu), aluminum (Al), ruthenium (Ru), silicides, or any other suitable conductive materials. For example, the material of the first conductive body 115 includes tungsten (W). A material of the first insulating isolation layer 116 may include one or more of silicon oxide (SiO₂), silicon nitride (Si₃N₄), silicon oxynitride (SiOₓN_{y}), or any other suitable insulation materials. In the case where the materials of the first insulating isolation layer 116 and the first insulation layer 111 are the same, there is no obvious interface therebetween.

In some implementations, the second contact structure T2 may comprise a second conductive body 125 and a second insulating isolation layer 126. The second insulating isolation layer 126 surrounds an outer side of the second conductive body 125. For example, the second conductive body 125 may have a roughly pillar-shaped structure, and the second insulating isolation layer 126 may have a roughly tube-shaped structure with openings at both ends. The second insulating isolation layer 126 may cover a sidewall of the second conductive body 125. A material of the second conductive body 125 may include one or more of titanium (Ti), titanium nitride (TiN), tantalum (Ta), tantalum nitride (TaN), polycrystalline silicon (poly-Si), amorphous silicon (a-Si), tungsten (W), molybdenum (Mo), copper (Gu), aluminum (Al), ruthenium (Ru), silicides, or any other suitable conductive materials. For example, the material of the second conductive body 125 includes tungsten (W). A material of the second insulating isolation layer 126 may include one or more of silicon oxide (SiO₂), silicon nitride (Si₃N₄), silicon oxynitride (SiOₓN_{y}), or any other suitable insulation materials. The second insulating isolation layer 126 is conducive to reducing the risk of electrical leakage between the first filling structure 114 and the second conductive body 125.

In some implementations, in the plane perpendicular to the direction D1, the size (e.g., diameter) of the first contact structure T1 is 50-300 nm, and the size (e.g., diameter) of the second contact structure T2 is 50-300 nm.

In some implementations, in the plane perpendicular to the direction D1, the size (e.g., diameter) of the first contact structure T1 is smaller than the size (e.g., diameter) of the second contact structure T2. This is conducive to reducing the process difficulty of forming the first contact structure T1 and the second contact structure T2 and increasing the yield of the package structure 100.

It is to be noted that the so-called comparison of “the size of the first contact structure T1 in the plane perpendicular to the direction D1” and “the size of the second contact structure T2 in the plane perpendicular to the direction D1” in the present application refers to the comparison of the sizes of the first contact structure T1 and the second contact structure T2 in the same plane perpendicular to the direction D1.

In some implementations, the package structure 100 may further comprise a first routing layer 113 between the first insulation layer 111 and the first die 112, and a second routing layer 123 located between the second insulation layer 121 and the second die 122. The first filling structure 114 extends into the first routing layer 113. The first routing layer 113 may be configured to rearrange a first pad structure on a surface of the first die 112, which is conducive to optimizing a layout of the first contact structure T1 in the plane perpendicular to the direction D1. Similarly, the second routing layer 123 may be configured to rearrange a second pad structure on a surface of the second die 122, which is conducive to optimizing a layout of the second contact structure T2 in the plane perpendicular to the direction D1.

In some implementations, the first routing layer 113 may comprise a first insulation material layer 1133, and at least one layer of first via structure 1132 and at least one layer of first interconnection line 1131 that are located in the first insulation material layer 1133. In other words, the number of layers of first interconnection line 1131 may be one or more. The number of layers of first via structure 1132 may be one or more. FIG. 1A shows that the number of layers of the first interconnection line 1131 is one and the number of layers of the first via structure 1132 is also one. The present application has no specific limitation on the number of layers of first interconnection line 1131 and the number of layers of first via structure 1132. For example, in the case of a plurality of layers of first interconnection line 1131 and a plurality of layers of first via structure 1132, the layers of first interconnection line 1131 and the layers of first via structure 1132 are arranged alternately in the direction D1, and one layer of first interconnection line 1131 or one layer of first via structure 1132 serves as an outer surface of the first routing layer 113.

In some implementations, a material of the first insulation material layer 1133 may include one or more of silicon oxide (SiO₂), silicon nitride (Si₃N₄), silicon oxynitride (SiOₓN_{y}), or any other suitable insulation materials. Materials of the first interconnection line 1131 and the first via structure 1132 may include one or more of titanium (Ti), titanium nitride (TiN), tantalum (Ta), tantalum nitride (TaN), polycrystalline silicon (poly-Si), amorphous silicon (a-Si), tungsten (W), molybdenum (Mo), copper (Gu), aluminum (Al), ruthenium (Ru), silicides, or any other suitable conductive materials. For example, the materials of the first interconnection line 1131 and the first via structure 1132 both are tungsten (W).

In some implementations, the first die 112 is connected with the first routing layer 113 (e.g., the first interconnection line 1131 or the first via structure 1132), and an end of the first contact structure T1 facing the first die 112 is connected with the first routing layer 113 (e.g., the first interconnection line 1131 or the first via structure 1132). In one implementation, a surface of the first die 112 facing the first routing layer 113 has a plurality of first pad structures (not shown), and the first pad structures is in contact with the first via structure 1132. The first contact structure T1 is in contact with the first interconnection line 1131. For example, the first conductive body 115 in the first contact structure T1 is in contact with the first interconnection line 1131. For example, the first contact structure T1 is connected with the first die 112 through the first interconnection line 1131 and the first via structure 1132.

In some implementations, the second routing layer 123 may comprise a second insulation material layer 1233, and at least one layer of second via structure 1232 and at least one layer of second interconnection line 1231 that are located in the second insulation material layer 1233. In other words, the number of layers of second interconnection line 1231 may be one or more. The number of layers of second via structure 1232 may be one or more. FIG. 1A shows that the number of layers of second interconnection line 1231 is one and the number of layers of second via structure 1232 is also one. The present application has no specific limitation on the number of layers of second interconnection line 1231 and the number of layers of second via structure 1232. For example, in the case of a plurality of layers of second interconnection line 1231 and a plurality of layers of second via structure 1232, the layers of second interconnection line 1231 and the layers of second via structure 1232 are arranged alternately in the direction D1, and one layer of second interconnection line 1231 or one layer of second via structure 1232 serves as an outer surface of the second routing layer 123.

In some implementations, a material of the second insulation material layer 1233 may include one or more of silicon oxide (SiO₂), silicon nitride (Si₃N₄), silicon oxynitride (SiOₓN_{y}), or any other suitable insulation materials. Materials of the second interconnection line 1231 and the second via structure 1232 may include one or more of titanium (Ti), titanium nitride (TiN), tantalum (Ta), tantalum nitride (TaN), polycrystalline silicon (poly-Si), amorphous silicon (a-Si), tungsten (W), molybdenum (Mo), copper (Gu), aluminum (Al), ruthenium (Ru), silicides, or any other suitable conductive materials. For example, the materials of the second interconnection line 1231 and the second via structure 1232 both are tungsten (W).

In some implementations, the second die 122 is connected with the second routing layer 123 (e.g., the second interconnection line 1231 or the second via structure 1232), and an end of the second contact structure T2 facing the second die 122 is connected with the second routing layer 123 (e.g., the second interconnection line 1231 or the second via structure 1232). In one implementation, a surface of the second die 122 facing the second routing layer 123 has a plurality of second pad structures (not shown), and the second pad structure is in contact with the second via structure 1232. The second contact structure T2 is in contact with the second interconnection line 1231. For example, the second conductive body 125 in the second contact structure T2 is in contact with the second interconnection line 1231. The second contact structure T2 is connected with the second die 122 through the second interconnection line 1231 and the second via structure 1232.

In some implementations, the package structure 100 may further comprise a second filling structure 124. The second filling structure 124 may extend through the second insulation layer 121 along the direction D1 and extend into the second routing layer 123. A material of the second filling structure 124 may include a semiconductor material, e.g., silicon. The second filling structure 124 may be located at a middle portion of the second insulation layer 121. In some examples, in the plane perpendicular to the direction D1, the second insulation layer 121 may surround the second filling structure 124. In some other examples, in the plane perpendicular to the direction D1, the second insulation layer 121 may surround a part of the second filling structure 124. The second filling structure 124 is conducive to reducing the process difficulty and manufacturing cost of forming a third contact structure T3 and increasing the yield of the package structure 100. The third contact structure T3 will be illustrated below.

It is to be noted that, in other implementations, in the case where no second routing layer 123 is disposed between the second insulation layer 121 and the second die 122, the second filling structure 124 extends through only the second insulation layer 121 along the direction D1.

In some implementations, a sidewall of the first filling structure 114 has a spacing distance from a sidewall of the second filling structure 124 in the direction D2. In an example, the sidewall of the first filling structure 114 also has a spacing distance from the sidewall of the second filling structure 124 in the direction D3. In this implementation, it can be ensured that the second contact structure T2 extends through the second insulation layer 121 but not through the second filling structure 124, which is conducive to optimizing a layout of the first contact structure T1 and the second contact structure T2 in the plane perpendicular to the direction D1.

In some implementations, the first routing layer 113 is in contact with the first insulation layer 111 and the first die 112 separately, and the first insulation layer 111, the first routing layer 113 and the first die 112 may serve as a first semiconductor structure 101. The second routing layer 123 is in contact with the second insulation layer 121 and the second die 122 separately, and the second insulation layer 121, the second routing layer 123 and the second die 122 may serve as a second semiconductor structure 102.

In some implementations, the first semiconductor structure 101 may be connected with the second semiconductor structure 102 by bonding. In one implementation, the first semiconductor structure 101 may be connected with the second semiconductor structure 102 by any “bonding technique” known in the art. The so-called “bonding technique” in the present application may include, but is not limited to, fusion bonding, anodic bonding, eutectic bonding and hybrid bonding.

In some implementations, on a side of the second die 122 facing away from the first insulation layer 111, the package structure 100 further comprises a third insulation layer 131, a third routing layer 133 and a third die 132 in sequence along the direction D1.

In some implementations, the third insulation layer 131 may be located on a side of the third die 132 facing the second die 122. For example, the third insulation layer 131 may extend laterally along the direction D2 and the direction D3. For another example, the second die 122 may be in contact with the third insulation layer 131.

In some implementations, the third routing layer 133 may be located between the third insulation layer 131 and the third die 132. The third routing layer 133 may comprise a third insulation material layer 1333, and at least one layer of third via structure 1332 and at least one layer of third interconnection line 1331 that are located in the third insulation material layer 1333. In other words, the number of layers of third interconnection line 1331 may be one or more. The number of layers of third via structure 1332 may be one or more. FIG. 1A shows that the number of layers of third interconnection line 1331 is one and the number of layers of third via structure 1332 is also one. The present application has no specific limitation on the number of layers of third interconnection line 1331 and the number of layers of third via structure 1332. For example, in the case of a plurality of layers of third interconnection line 1331 and a plurality of layers of third via structure 1332, the layers of third interconnection line 1331 and the layers of third via structure 1332 are arranged alternately in the direction D1, and one layer of third interconnection line 1331 or one layer of third via structure 1332 serves as an outer surface of the third routing layer 133.

In some implementations, a material of the third insulation material layer 1333 may include one or more of silicon oxide (SiO₂), silicon nitride (Si₃N₄), silicon oxynitride (SiOₓN_{y}), or any other suitable insulation materials. Materials of the third interconnection line 1331 and the third via structure 1332 may include one or more of titanium (Ti), titanium nitride (TiN), tantalum (Ta), tantalum nitride (TaN), polycrystalline silicon (poly-Si), amorphous silicon (a-Si), tungsten (W), molybdenum (Mo), copper (Gu), aluminum (Al), ruthenium (Ru), silicides, or any other suitable conductive materials. For example, the materials of the third interconnection line 1331 and the third via structure 1332 both are tungsten (W).

In some implementations, the third die 132 may be a die stack or a single die. For example, the third die 132 may be a die stack constituted by connecting a memory array structure and a peripheral circuit structure by bonding. In some implementations, a substrate material of the third die 132 may include a semiconductor material, for example, at least one of monocrystalline silicon, polycrystalline silicon, monocrystalline germanium, a group III-V compound semiconductor material, a group II-VI compound semiconductor material, or other semiconductor materials known in the art. For example, the substrate material of the third die 132 may include silicon.

In some implementations, the package structure 100 may further comprise a third filling structure 134. The third filling structure 134 may extend through the third insulation layer 131 along the direction D1 and extend into the third routing layer 133. A material of the third filling structure 134 may include a semiconductor material, e.g., silicon. The third filling structure 134 may be located at a middle portion of the third insulation layer 131. In some examples, in the plane perpendicular to the direction D1, the third insulation layer 131 may surround the third filling structure 134. In some other examples, in the plane perpendicular to the direction D1, the third insulation layer 131 may surround a part of the third filling structure 134. The third filling structure 134 is conducive to reducing the process difficulty and manufacturing cost of forming a fourth contact structure T4 and increasing the yield of the package structure 100. The fourth contact structure T4 will be illustrated below.

In some implementations, a sidewall of the second filling structure 124 has a spacing distance from a sidewall of the third filling structure 134 in the direction D2. In an example, the sidewall of the second filling structure 124 also has a spacing distance from the sidewall of the third filling structure 134 in the direction D3. In this implementation, it can be ensured that the third contact structure T3 extends through the third insulation layer 131 but not through the third filling structure 134, which is conducive to optimizing a layout of the first contact structure T1, the second contact structure T2 and the third contact structure T3 in the plane perpendicular to the direction D1.

In some implementations, the package structure 100 may further comprise a third contact structure T3. The third contact structure T3 may sequentially extend through the first filling structure 114, the first die 112, the second filling structure 124, the second die 122 and the third insulation layer 131 along the direction D1.

In some implementations, the third contact structure T3 may comprise a third conductive body 135 and a third insulating isolation layer 136. The third insulating isolation layer 136 surrounds an outer side of the third conductive body 135. For example, the third conductive body 135 may have a roughly pillar-shaped structure, and the third insulating isolation layer 136 may have a roughly tube-shaped structure with openings at both ends. The third insulating isolation layer 136 may cover a sidewall of the third conductive body 135. A material of the third conductive body 135 may include one or more of titanium (Ti), titanium nitride (TiN), tantalum (Ta), tantalum nitride (TaN), polycrystalline silicon (poly-Si), amorphous silicon (a-Si), tungsten (W), molybdenum (Mo), copper (Gu), aluminum (Al), ruthenium (Ru), silicides, or any other suitable conductive materials. For example, the material of the third conductive body 135 includes tungsten (W). A material of the third insulating isolation layer 136 may include one or more of silicon oxide (SiO₂), silicon nitride (Si₃N₄), silicon oxynitride (SiOₓN_{y}), or any other suitable insulation materials. The third insulating isolation layer 136 is conducive to reducing the risk of electrical leakage between the first filling structure 114 and the third conductive body 135 and between the second filling structure 124 and the third conductive body 135.

In some implementations, the third die 132 is connected with the third routing layer 133 (e.g., the third interconnection line 1331 or the third via structure 1332), and an end of the third contact structure T3 facing the third die 132 is connected with the third routing layer 133 (e.g., the third interconnection line 1331 or the third via structure 1332). In one implementation, a surface of the third die 132 facing the third routing layer 133 has a plurality of third pad structures (not shown), and the third pad structure is in contact with the third via structure 1332. The third contact structure T3 is in contact with the third interconnection line 1331. For example, the third conductive body 135 in the third contact structure T3 is in contact with the third interconnection line 1331. The third contact structure T3 is connected with the third die 132 through the third interconnection line 1331 and the third via structure 1332.

In some implementations, the third routing layer 133 is in contact with the third insulation layer 131 and the third die 132 separately, and the third insulation layer 131, the third routing layer 133 and the third die 132 serve as a third semiconductor structure 103. The third semiconductor structure 103 is connected with the second semiconductor structure 102 by bonding. In one implementation, the third semiconductor structure 103 may be connected with the second semiconductor structure 102 by any “bonding technique” known in the art. The so-called “bonding technique” in the present application may include, but is not limited to, fusion bonding, anodic bonding, eutectic bonding and hybrid bonding.

In some implementations, on a side of the third die 132 facing away from the first insulation layer 111, the package structure 100 further comprises a fourth insulation layer 141, a fourth routing layer 143 and a fourth die 142 in sequence along the direction D1.

In some implementations, the fourth insulation layer 141 may be located on a side of the fourth die 142 facing the third die 132. For example, the fourth insulation layer 141 may extend laterally along the direction D2 and the direction D3. For another example, the third die 132 may be in contact with the fourth insulation layer 141.

In some implementations, the fourth routing layer 143 may be located between the fourth insulation layer 141 and the fourth die 142. The fourth routing layer 143 may comprise a fourth insulation material layer 1433, and at least one layer of fourth via structure 1432 and at least one layer of fourth interconnection line 1431 that are located in the fourth insulation material layer 1433. In other words, the number of layers of fourth interconnection line 1431 may be one or more. The number of layers of fourth via structure 1432 may be one or more. FIG. 1A shows that the number of layers of fourth interconnection line 1431 is one and the number of layers of fourth via structure 1432 is also one. The present application has no specific limitation on the number of layers of fourth interconnection line 1431 and the number of layers of fourth via structure 1432. For example, in the case of a plurality of layers of fourth interconnection line 1431 and a plurality of layers of fourth via structure 1432, the layers of fourth interconnection line 1431 and the layers of fourth via structure 1432 are arranged alternately in the direction D1, and one layer of fourth interconnection line 1431 or one layer of fourth via structure 1432 serves as an outer surface of the fourth routing layer 143.

In some implementations, a material of the fourth insulation material layer 1433 may include one or more of silicon oxide (SiO₂), silicon nitride (Si₃N₄), silicon oxynitride (SiOₓN_{y}), or any other suitable insulation materials. Materials of the fourth interconnection line 1431 and the fourth via structure 1432 may include one or more of titanium (Ti), titanium nitride (TiN), tantalum (Ta), tantalum nitride (TaN), polycrystalline silicon (poly-Si), amorphous silicon (a-Si), tungsten (W), molybdenum (Mo), copper (Gu), aluminum (Al), ruthenium (Ru), silicides, or any other suitable conductive materials. For example, the materials of the fourth interconnection line 1431 and the fourth via structure 1432 both are tungsten (W).

In some implementations, the fourth die 142 may be a die stack or a single die. For example, the fourth die 142 may be a die stack constituted by connecting a memory array structure and a peripheral circuit structure by bonding. In some implementations, a substrate material of the fourth die 142 may include a semiconductor material, for example, at least one of monocrystalline silicon, polycrystalline silicon, monocrystalline germanium, a group III-V compound semiconductor material, a group II-VI compound semiconductor material, or other semiconductor materials known in the art. For example, the substrate material of the fourth die 142 may include silicon.

In some implementations, the package structure 100 may further comprise a fourth contact structure T4. The fourth contact structure T4 may sequentially extend through the first filling structure 114, the first die 112, the second filling structure 124, the second die 122, the third filling structure 134 and the fourth insulation layer 141 along the direction D1.

In some implementations, the fourth contact structure T4 may comprise a fourth conductive body 145 and a fourth insulating isolation layer 146. The fourth insulating isolation layer 146 surrounds an outer side of the fourth conductive body 145. For example, the fourth conductive body 145 may have a roughly pillar-shaped structure, and the fourth insulating isolation layer 146 may have a roughly tube-shaped structure with openings at both ends. The fourth insulating isolation layer 146 may cover a sidewall of the fourth conductive body 145. A material of the fourth conductive body 145 may include one or more of titanium (Ti), titanium nitride (TiN), tantalum (Ta), tantalum nitride (TaN), polycrystalline silicon (poly-Si), amorphous silicon (a-Si), tungsten (W), molybdenum (Mo), copper (Gu), aluminum (Al), ruthenium (Ru), silicides, or any other suitable conductive materials. For example, the material of the fourth conductive body 145 includes tungsten (W). A material of the fourth insulating isolation layer 146 may include one or more of silicon oxide (SiO₂), silicon nitride (Si₃N₄), silicon oxynitride (SiOₓN_{y}), or any other suitable insulation materials. The fourth insulating isolation layer 146 is conducive to reducing the risk of electrical leakage between the first filling structure 114 and the fourth conductive body 145, between the second filling structure 124 and the fourth conductive body 145 and between the third filling structure 134 and the fourth conductive body 145.

In some implementations, the fourth die 142 is connected with the fourth routing layer 143 (e.g., the fourth interconnection line 1431 or the fourth via structure 1432), and an end of the fourth contact structure T4 facing the fourth die 142 is connected with the fourth routing layer 143 (e.g., the fourth interconnection line 1431 or the fourth via structure 1432). In one implementation, a surface of the fourth die 142 facing the fourth routing layer 143 has a plurality of fourth pad structures 148, and the fourth pad structures 148 are in contact with the fourth via structure 1432. The fourth contact structure T4 is in contact with the fourth interconnection line 1431. For example, the fourth conductive body 145 of the fourth contact structure T4 is in contact with the fourth interconnection line 1431. The fourth contact structure T4 is connected with the fourth die 142 through the fourth interconnection line 1431 and the fourth via structure 1432.

In some implementations, the fourth routing layer 143 is in contact with the fourth insulation layer 141 and the fourth die 142 separately, and the fourth insulation layer 141, the fourth routing layer 143 and the fourth die 142 serve as a fourth semiconductor structure 104. The fourth semiconductor structure 104 is connected with the third semiconductor structure 103 by bonding. In one implementation, the fourth semiconductor structure 104 may be connected with the third semiconductor structure 103 by any “bonding technique” known in the art. The so-called “bonding technique” in the present application may include, but is not limited to, fusion bonding, anodic bonding, eutectic bonding and hybrid bonding.

It is to be noted that FIGS. 1A and 1B show that the number of the third semiconductor structure 103 between the second semiconductor structure 102 and the fourth semiconductor structure 104 is one. In other implementations, the number of the third semiconductor structure 103 may be greater than one (not shown). In this case, a plurality of third semiconductor structures 103 may be arranged along the direction D1, and adjacent ones of the third semiconductor structures 103 are connected by bonding. In one implementation, adjacent ones of the third semiconductor structures 103 may be connected by any “bonding technique” known in the art. The so-called “bonding technique” in the present application may include, but is not limited to, fusion bonding, anodic bonding, eutectic bonding and hybrid bonding.

In some implementations, in the plane perpendicular to the direction D1, the size (e.g., diameter) of the third contact structure T3 is 50-300 nm, and the size (e.g., diameter) of the fourth contact structure T4 is 50-300 nm.

In some implementations, in the plane perpendicular to the direction D1, the size (e.g., diameter) of the second contact structure T2 is smaller than the size (e.g., diameter) of the third contact structure T3, and the size (e.g., diameter) of the third contact structure T3 is smaller than the size (e.g., diameter) of the fourth contact structure T4. It is to be noted that the so-called comparison of “the size of the second contact structure T2 in the plane perpendicular to the direction D1” and “the size of the third contact structure T3 in the plane perpendicular to the direction D1” in the present application refers to the comparison of the sizes of the second contact structure T2 and the third contact structure T3 in the same plane perpendicular to the direction D1. Similarly, the so-called comparison of “the size of the third contact structure T3 in the plane perpendicular to the direction D1” and “the size of the fourth contact structure T4 in the plane perpendicular to the direction D1” in the present application refers to the comparison of the sizes of the third contact structure T3 and the fourth contact structure T4 in the same plane perpendicular to the direction D1.

In some implementations, in the plane perpendicular to the direction D1, the sizes (e.g., diameters) of the first contact structure T1, the second contact structure T2, the third contact structure T3 and the fourth contact structure T4 increase gradually. It is to be noted that the so-called comparison of “the sizes of the first contact structure T1 to the fourth contact structure T4 in the plane perpendicular to the direction D1” in the present application refers to the comparison of the sizes of the first contact structure T1 to the fourth contact structure T4 in the same plane perpendicular to the direction D1.

In some implementations, the package structure 100 may further comprise a first dielectric layer 117. The first dielectric layer 117 may be located on the sidewall of the first filling structure 114 and on a surface of the first filling structure 114 facing the first die 112, and be in contact with the first die 112. A material of the first dielectric layer 117 may include one or more of silicon oxide (SiO₂), silicon nitride (Si₃N₄), silicon oxynitride (SiOₓN_{y}), or any other suitable insulation materials. For example, the material of the first dielectric layer 117 may include silicon oxide (SiO₂). The part of the first dielectric layer 117 located on the sidewall of the first filling structure 114 can reduce the risk of electrical leakage between the first routing layer 113 (e.g., the first via structure 1132 or the first interconnection line 1131) and the first filling structure 114.

In some implementations, the package structure 100 may further comprise a second dielectric layer 127. The second dielectric layer 127 may be located on the sidewall of the second filling structure 124 and on a surface of the second filling structure 124 facing the second die 122, and be in contact with the second die 122. A material of the second dielectric layer 127 may include one or more of silicon oxide (SiO₂), silicon nitride (Si₃N₄), silicon oxynitride (SiOₓN_{y}), or any other suitable insulation materials. For example, the material of the second dielectric layer 127 may include silicon oxide (SiO₂). The part of the second dielectric layer 127 located on the sidewall of the second filling structure 124 can reduce the risk of electrical leakage between the second routing layer 123 (e.g., the second via structure 1232 or the second interconnection line 1231) and the second filling structure 124.

In some implementations, the package structure 100 may further comprise a third dielectric layer 137. The third dielectric layer 137 may be located on the sidewall of the third filling structure 134 and on a surface of the third filling structure 134 facing the third die 132, and be in contact with the third die 132. A material of the third dielectric layer 137 may include one or more of silicon oxide (SiO₂), silicon nitride (Si₃N₄), silicon oxynitride (SiOₓN_{y}), or any other suitable insulation materials. For example, the material of the third dielectric layer 137 may include silicon oxide (SiO₂). The part of the third dielectric layer 137 located on the sidewall of the third filling structure 134 can reduce the risk of electrical leakage between the third routing layer 133 (e.g., the third via structure 1332 or the third interconnection line 1331) and the third filling structure 134.

In some implementations, the package structure 100 may further comprise a circuit board 151 and a connection structure 152. The circuit board 151 may be located on a side of the first insulation layer 111 facing away from the first die 112. For example, the circuit board 151 may include one or more of a printed circuit board, a flexible circuit board, or any other suitable types of circuit boards. The connection structure 152 may be connected between the circuit board 151 and the first contact structure T1 to the fourth contact structure T4. For example, the connection structure 152 may comprise a solder ball.

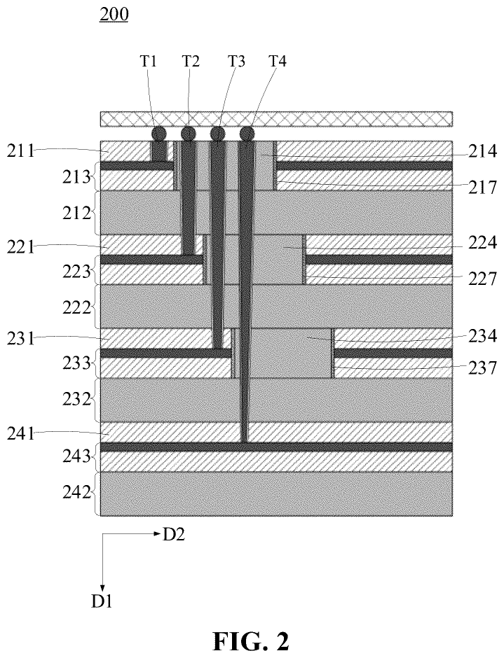

FIG. 2 is a schematic cross-sectional view of a package structure according to another example of the present application. For the purpose of concise description, the same contents as the previous example will be no longer described in the following examples.

As shown in FIG. 2, the package structure 200 comprises a first insulation layer 211, a first die 212, a second insulation layer 221 and a second die 222 in sequence along a direction D1. The package structure 200 further comprises a first filling structure 214, a first contact structure T1 and a second contact structure T2. The first filling structure 214 extends through the first insulation layer 211 along the direction D1. The first contact structure T1 extends through the first insulation layer 211 along the direction D1. The second contact structure T2 extends through the first filling structure 214, the first die 212 and the second insulation layer 221 along the direction D1.

In some implementations, the package structure 200 may further comprise a first routing layer 213 between the first insulation layer 211 and the first die 212, and a second routing layer 223 between the second insulation layer 221 and the second die 222.

In some implementations, the first filling structure 214 may be located at a middle portion of the first insulation layer 211 and extend into the first routing layer 213. In some examples, in a plane perpendicular to the direction D1, the first insulation layer 211 may surround the first filling structure 214. In some other examples, in the plane perpendicular to the direction D1, the first insulation layer 211 may surround a part of the first filling structure 214.

In some implementations, the package structure 200 may further comprise a first dielectric layer 217. The first dielectric layer 217 may be located on a sidewall of the first filling structure 214. The first filling structure 214 is in contact with the second die 222. The first dielectric layer 217 can reduce the risk of electrical leakage between the first routing layer 213 and the first filling structure 214, and make the first contact structure T1 not need to extend through the first dielectric layer 217, which is conducive to reducing the process difficulty and manufacturing cost of the first contact structure T1 and increasing the yield of the package structure 200.

In some implementations, on a side of the second die 222 facing away from the first insulation layer 211, the package structure 200 may further comprise a third insulation layer 231, a third routing layer 233, a third die 232, a fourth insulation layer 241, a fourth routing layer 243 and a fourth die 242 in sequence along the direction D1. Moreover, the package structure 200 may further comprise a second filling structure 224, a third filling structure 234, a third contact structure T3 and a fourth contact structure T4.

In some implementations, the second filling structure 224 extends through the second insulation layer 221 and extends into the second routing layer 223. The third filling structure 234 extends through the third insulation layer 231 and extends into the third routing layer 233.

In some implementations, the third contact structure T3 sequentially extends through the first filling structure 214, the first die 212, the second filling structure 224, the second die 222 and the third insulation layer 231 until reaching the third routing layer 233, and is connected with the third die 232 through the third routing layer 233. The fourth contact structure T4 sequentially extends through the first filling structure 214, the first die 212, the second filling structure 224, the second die 222, the third filling structure 234, the third die 232 and the fourth insulation layer 241 until reaching the fourth routing layer 243, and is connected with the fourth die 242 through the fourth routing layer 243.

In some implementations, the package structure 200 may further comprise a second dielectric layer 227 and a third dielectric layer 237. The second dielectric layer 227 may be located on a sidewall of the second filling structure 224. The second filling structure 224 is in contact with the third die 232. The third dielectric layer 237 may be located on a sidewall of the third filling structure 234. The third filling structure 234 is in contact with the fourth die 242. The second dielectric layer 227 can reduce the risk of electrical leakage between the second routing layer 223 and the second filling structure 224, and make the second contact structure T2 not need to extend through the second dielectric layer 227, which is conducive to reducing the process difficulty and manufacturing cost of the second contact structure T2 and increasing the yield of the package structure 200. Similarly, the third dielectric layer 237 can reduce the risk of electrical leakage between the third routing layer 233 and the third filling structure 234, and make the third contact structure T3 not need to extend through the third dielectric layer 237, which is conducive to reducing the process difficulty and manufacturing cost of the third contact structure T3 and increasing the yield of the package structure 200.

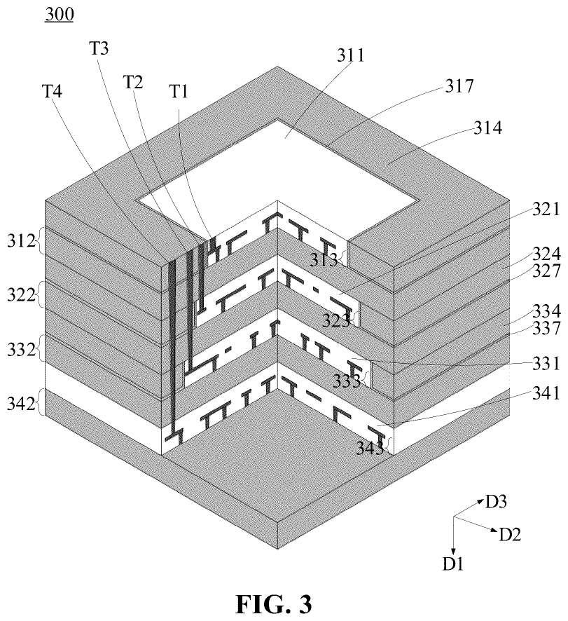

FIG. 3 is a perspective view of a package structure according to yet another example of the present application. In order to show an internal structure of the package structure 300 more clearly, part of the package structure 300 is removed in FIG. 3 to expose the internal structure of the package structure 300.

As shown in FIG. 3, the package structure 300 comprises a first insulation layer 311, a first die 312, a second insulation layer 321 and a second die 322 in sequence along a direction D1. The package structure 300 further comprises a first filling structure 314, a first contact structure T1 and a second contact structure T2. The first filling structure 314 extends through the first insulation layer 311 along the direction D1. The first contact structure T1 extends through the first insulation layer 311 along the direction D1. The second contact structure T2 extends through the first filling structure 314, the first die 312 and the second insulation layer 321 along the direction D1.

In some implementations, the first filling structure 314 may be located at a periphery of the first insulation layer 311. In some examples, in a plane perpendicular to the direction D1, the first filling structure 314 may surround the first insulation layer 311. In some other examples, in the plane perpendicular to the direction D1, the first filling structure 314 may surround a part of the first insulation layer 311. The first filling structure 314 is conducive to reducing the process difficulty and manufacturing cost of forming the second contact structure T2 and increasing the yield of the package structure 300.

In some implementations, the package structure 300 may further comprise a first routing layer 313 between the first insulation layer 311 and the first die 312, and a second routing layer 323 between the second insulation layer 321 and the second die 322.

In some implementations, the first filling structure 314 may extend into the first routing layer 313 along the direction D1.

In some implementations, the package structure 300 may further comprise a first dielectric layer 317. The first dielectric layer 317 may be located on a sidewall of the first filling structure 314 and on a surface of the first filling structure 314 facing the first die 312, and be in contact with the first die 312. A material of the first dielectric layer 317 may include one or more of silicon oxide (SiO₂), silicon nitride (Si₃N₄), silicon oxynitride (SiOₓN_{y}), or any other suitable insulation materials. For example, the material of the first dielectric layer 317 may include silicon oxide (SiO₂). The part of the first dielectric layer 317 located on the sidewall of the first filling structure 314 can reduce the risk of electrical leakage between the first routing layer 313 and the first filling structure 314.

In some implementations, on a side of the second die 322 facing away from the first insulation layer 311, the package structure 300 may further comprise a third insulation layer 331, a third routing layer 333, a third die 332, a fourth insulation layer 341, a fourth routing layer 343 and a fourth die 342 in sequence along the direction D1. Moreover, the package structure 300 may further comprise a second filling structure 324, a third filling structure 334, a third contact structure T3 and a fourth contact structure T4.

In some implementations, the second filling structure 324 may extend through the second insulation layer 321 and extend into the second routing layer 323. The third filling structure 334 may extend through the third insulation layer 331 and extend into the third routing layer 333.

In some implementations, the third contact structure T3 may sequentially extend through the first filling structure 314, the first die 312, the second filling structure 324, the second die 322 and the third insulation layer 331 until reaching the third routing layer 333, and be connected with the third die 332 through the third routing layer 333. The fourth contact structure T4 may sequentially extend through the first filling structure 314, the first die 312, the second filling structure 324, the second die 322, the third filling structure 334, the third die 332 and the fourth insulation layer 341 until reaching the fourth routing layer 343, and be connected with the fourth die 342 through the fourth routing layer 343.

In some implementations, the second filling structure 324 may be located at a periphery of the second insulation layer 321. The third filling structure 334 may be located at a periphery of the third insulation layer 331.

In some implementations, the package structure 300 may further comprise a second dielectric layer 327 and a third dielectric layer 337. The second dielectric layer 327 may be located on a sidewall of the second filling structure 324 and on a surface of the second filling structure 324 facing the second die 322, and be in contact with the second die 322. The third dielectric layer 337 may be located on a sidewall of the third filling structure 334 and on a surface of the third filling structure 334 facing the third die 332, and be in contact with the third die 332. The second dielectric layer 327 can reduce the risk of electrical leakage between the second routing layer 323 and the second filling structure 324. Similarly, the third dielectric layer 337 can reduce the risk of electrical leakage between the third routing layer 333 and the third filling structure 334.

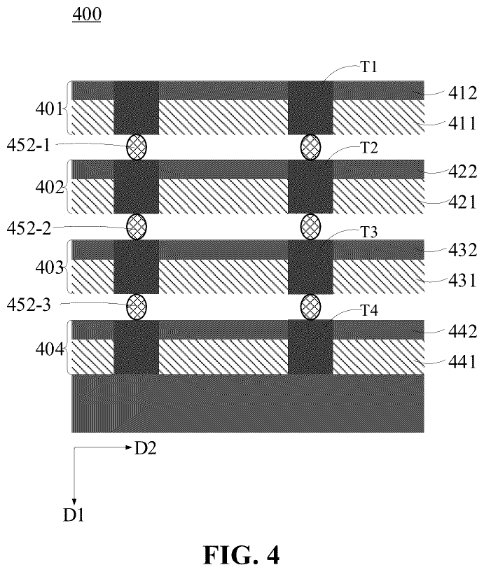

FIG. 4 is a schematic cross-sectional view of a package structure provided by still another example of the present application.

As shown in FIG. 4, the package structure 400 comprises a first semiconductor structure 401, a second semiconductor structure 402, a third semiconductor structure 403 and a fourth semiconductor structure 404 in sequence along a direction D1. The first semiconductor structure 401 may comprise a first insulation layer 411 and a first die 412 along the direction D1 and further comprise a first contact structure T1 extending through the first insulation layer 411 and the first die 412. The second semiconductor structure 402 may comprise a second insulation layer 421 and a second die 422 along the direction D1 and further comprise a second contact structure T2 extending through the second insulation layer 421 and the second die 422. The third semiconductor structure 403 may comprise a third insulation layer 431 and a third die 432 along the direction D1 and further comprise a third contact structure T3 extending through the third insulation layer 431 and the third die 432. The fourth semiconductor structure 404 may comprise a fourth insulation layer 441 and a fourth die 442 along the direction D1 and further comprise a fourth contact structure T4 extending through the fourth insulation layer 441 and the fourth die 442.

The package structure 400 may further comprise a first connection structure 452-1, a second connection structure 452-2 and a third connection structure 452-3. The first connection structure 452-1 is in contact with the first contact structure T1 and the second contact structure T2 to realize the connection of the first semiconductor structure 401 and the second semiconductor structure 402. The second connection structure 452-2 is in contact with the second contact structure T2 and the third contact structure T3 to realize the connection of the second semiconductor structure 402 and the third semiconductor structure 403. The third connection structure 452-3 is in contact with the third contact structure T3 and the fourth contact structure T4 to realize the connection of the third semiconductor structure 403 and the fourth semiconductor structure 404.

Compared with the package structure 400 shown in FIG. 4, the sizes of the package structures 100-300 provided by the above examples of the present application can be compressed in the direction D1 so that their vertical integration level can be increased. Besides, the conductive impedance can be reduced, the transmission time can be reduced, and the connection density and the transmission speed can be increased, thereby being conducive to follow the development trend of high bandwidth.

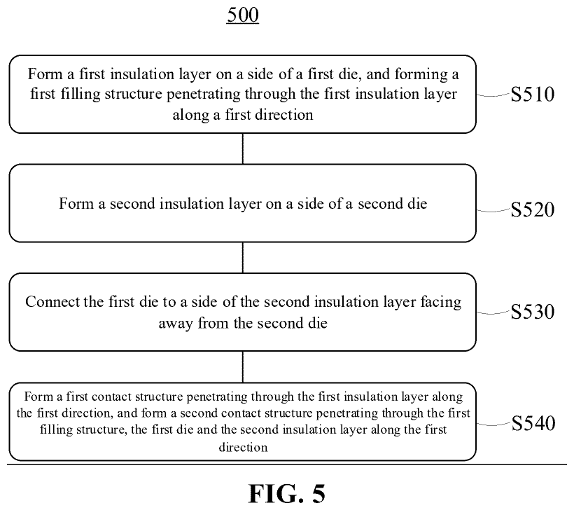

Some examples of the present application further provide a fabrication method of a package structure. FIG. 5 is a flow diagram of a fabrication method of a package structure provided by one example of the present application. As shown in FIG. 5, the fabrication method 500 of the package structure (hereinafter referred to as the fabrication method 500) may comprise:
S510, forming a first insulation layer on a side of a first die, and forming a first filling structure extending through the first insulation layer along a first direction;
S520, forming a second insulation layer on a side of a second die;
S530, connecting the first die to a side of the second insulation layer facing away from the second die; and
S540, forming a first contact structure extending through the first insulation layer along the first direction, and forming a second contact structure extending through the first filling structure, the first die and the second insulation layer along the first direction.

According to the fabrication method 400 provided by the example of the present application, the first die is connected to the side of the second insulation layer facing away from the second die, so that the size of the fabricated package structure can be compressed; and the first contact structure extending through the first insulation layer along the first direction are formed, and the second contact structure extending through the first filling structure, the first die and the second insulation layer along the first direction are formed, so that the process difficulty and process cost of the first contact structure and the second contact structure can be reduced, the fabrication time can be shortened, and the fabrication efficiency can be improved.

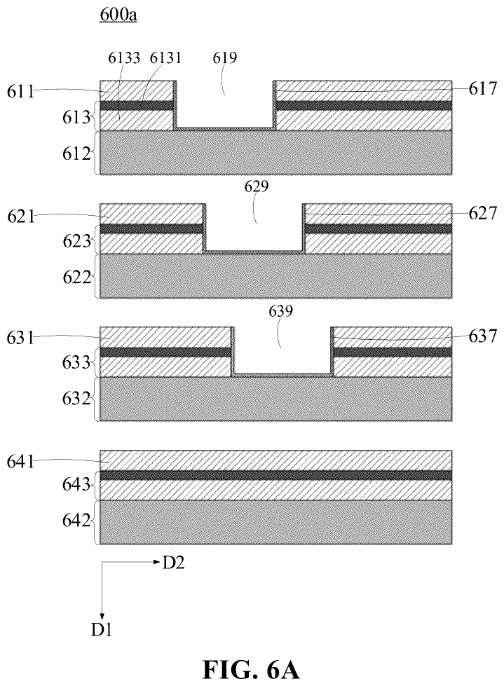

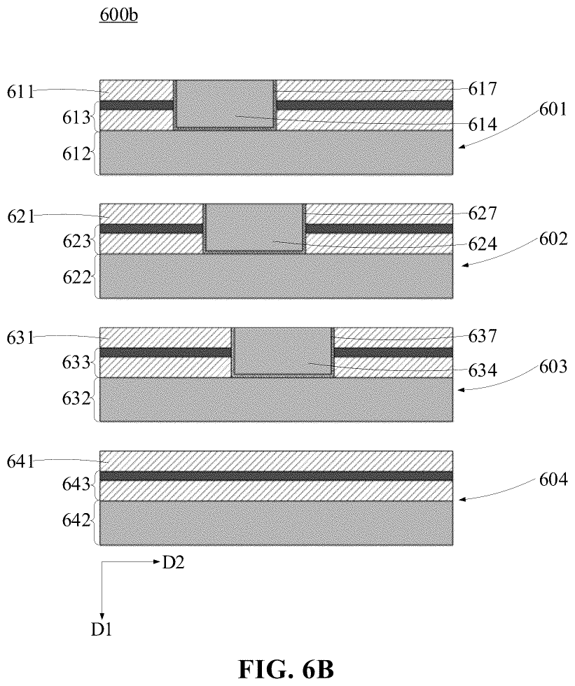

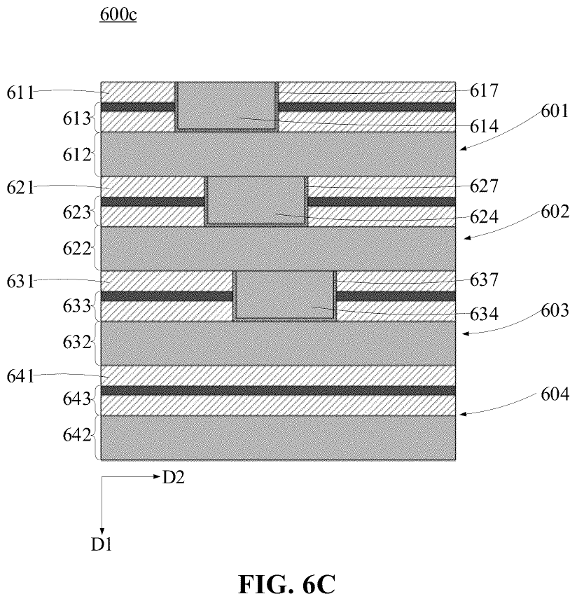

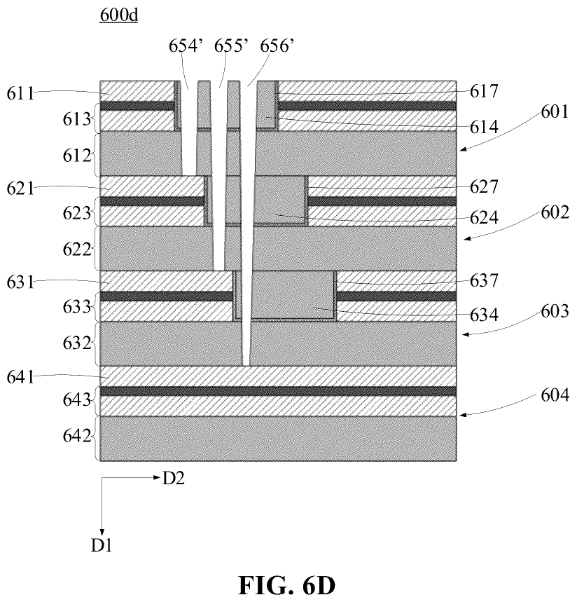

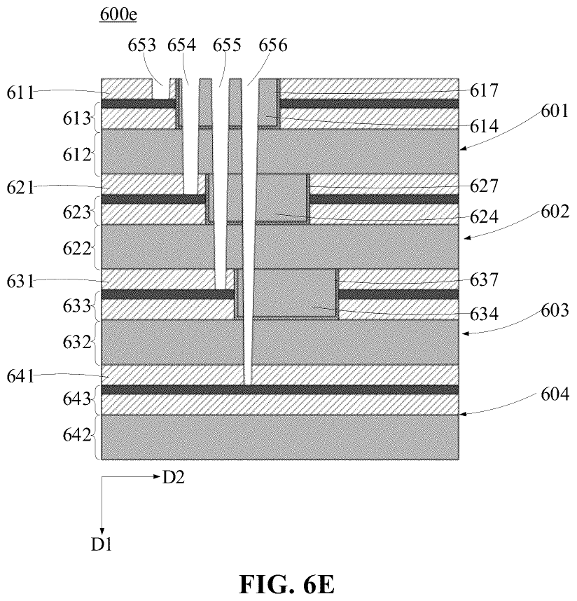

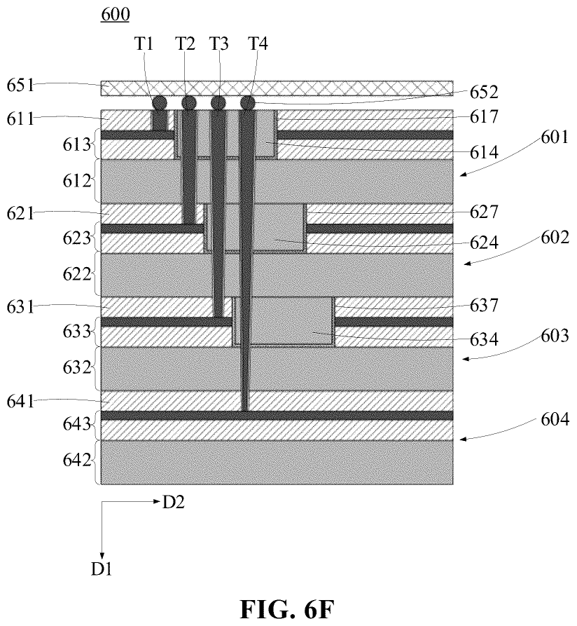

FIGS. 6A to 6F are schematic cross-sectional views of a package structure provided by one example of the present application during a fabrication process. For example, the package structure 100 shown in FIGS. 1A and 1B are formed in FIGS. 6A to 6F. The fabrication method 500 comprising operations S510 to S540 are illustrated below as an example in conjunction with FIGS. 6A to 6F.

### S510

FIG. 6A shows an intermediate structure 600a after forming a first insulation layer 611 on a side of a first die 612 and forming a second insulation layer 621 on a side of a second die 622. FIG. 6B shows an intermediate structure 600b after forming a first filling structure 614.

As shown in FIGS. 6A and 6B, the first insulation layer 611 may be formed on a side of the first die 612 by using a thin film deposition process such as chemical vapor deposition (CVD), physical vapor deposition (PVD), atomic layer deposition (ALD) or any combination thereof, and the first filling structure 614 extending through the first insulation layer 611 along the direction D1 may be formed by etching (e.g., at least one of dry etching or wet etching) and the thin film deposition process such as CVD, PVD, ALD or any combination thereof.

In some implementations, a first routing layer 613 may be formed between the first die 612 and the first insulation layer 611. For example, before forming the first insulation layer 611, the first routing layer 613 is formed on a surface of the first die 612, and the first insulation layer 611 is then formed on a surface of the first routing layer 613 facing away from the first die 612.

In some implementations, forming the first routing layer 613 may comprise the following operations. Firstly, one first insulation material sub-layer of a first insulation material layer 6133 is formed on the surface of the first die 612. A first via structure (not shown, referring to the first via structure 1132 shown in FIG. 1A) extending through the first insulation material sub-layer may be then formed. Next, another first insulation material sub-layer covering the above-mentioned first insulation material sub-layer and the first via structure may be formed. Subsequently, a first interconnection line 6131 extending through the first insulation material sub-layer may be formed. In an example, the first via structure and the first interconnection line 6131 may be formed alternately by a process described above. The first insulation material sub-layers may be jointly referred to as the first insulation material layer 6133. Thus, the first via structure and the first interconnection line 6131 may be formed in the first insulation material layer 6133.

In some implementations, as shown in FIGS. 6A and 6B, a first opening 619 extending through the first insulation layer 611 along the direction D1 may be formed by an etching (e.g., dry etching and/or wet etching) process. In an example, in the case that the first routing layer 613 is formed, the first opening 619 further extends through the first routing layer 613 and terminates, e.g., at the surface of the first die 612. Next, a first dielectric layer 617 may be formed on an inner wall of the first opening 619 by using a thin film deposition process such as CVD, PVD, ALD or any combination thereof. Subsequently, the first filling structure 614 may be formed in the first opening 619 where the first dielectric layer 617 is formed, by using a thin film deposition process such as CVD, PVD, ALD or any combination thereof.

In some implementations, the first die 612, the first insulation layer 611 and the first filling structure 614 may be referred to as a first semiconductor structure 601. In an example, in the case that the fabrication method 500 comprises forming the first routing layer 613 and the first dielectric layer 617, the first semiconductor structure 601 may further comprise the above-mentioned structures.

### S520

As shown in FIGS. 6A and 6B, the second insulation layer 621 may be formed on a side of the second die 622 by using a thin film deposition process such as CVD, PVD, ALD or any combination thereof.

In some implementations, a second routing layer 623 may be formed between the second die 622 and the second insulation layer 621. For example, before forming the second insulation layer 621, the second routing layer 623 is formed on a surface of the second die 622, and the second insulation layer 621 is then formed on a surface of the second routing layer 623 facing away from the second die 622.

In some implementations, a second filling structure 624 extending through the second insulation layer 621 along the direction D1 may be formed. For example, a second opening 629 extending through the second insulation layer 621 along the direction D1 may be formed by using an etching (e.g., dry etching and/or wet etching) process. In an example, in the case that the second routing layer 623 is formed, the second opening 629 further extends through the second routing layer 623 and terminates, e.g., at the surface of the second die 622. Next, a second dielectric layer 627 may be formed on an inner wall of the second opening 629 by using a thin film deposition process such as CVD, PVD, ALD or any combination thereof. Subsequently, the second filling structure 624 is formed in the second opening 629 where the second dielectric layer 627 is formed, by using a thin film deposition process such as CVD, PVD, ALD or any combination thereof.

In some implementations, the second die 622 and the second insulation layer 621 may be referred to as a second semiconductor structure 602. In an example, in the case that the fabrication method 500 comprises forming the second routing layer 623 and the second dielectric layer 627, the second semiconductor structure 602 may further comprise the above-mentioned structures.

In some implementations, as shown in FIGS. 6A and 6B, the fabrication method 500 may further comprise: sequentially forming a third routing layer 633 and a third insulation layer 631 on a side of a third die 632; forming a third opening 639 extending through the third insulation layer 631 and the third routing layer 633 and terminating at the third die 632; and forming a third dielectric layer 637 on an inner wall of the third opening 639 and forming a third filling structure 634 on an inner side of the third dielectric layer 637.

In some implementations, as shown in FIGS. 6A and 6B, the fabrication method 500 may further comprise: sequentially forming a fourth routing layer 643 and a fourth insulation layer 641 on a side of a fourth die 642.

In some implementations, the third die 632, the third routing layer 633, the third insulation layer 631, the third dielectric layer 637 and the third filling structure 634 may be referred to as a third semiconductor structure 603. The fourth die 642, the fourth routing layer 643 and the fourth insulation layer 641 may be referred to as a fourth semiconductor structure 604.

In some implementations, the first filling structure 614 may be located at a middle portion of the first insulation layer 611.

In some implementations, the second filling structure 624 may be located at a middle portion of the second insulation layer 621.

In some implementations, the third filling structure 634 may be located at a middle portion of the third insulation layer 631.

In some implementations, a sidewall of the first filling structure 614 has a spacing distance from a sidewall of the second filling structure 624.

In some implementations, a sidewall of the second filling structure 624 has a spacing distance from a sidewall of the third filling structure 634.

It is to be noted that the first semiconductor structure 601, the second semiconductor structure 602, the third semiconductor structure 603 and the fourth semiconductor structure 604 described above may be fabricated in parallel to improve the fabrication efficiency.

### S530

FIG. 6C shows an intermediate structure 600c after connecting the first die 612 to a side of the second insulation layer 621 facing away from the second die 622.

As shown in FIG. 6C, the first die 612 may be connected to the side of the second insulation layer 621 facing away from the second die 622. For example, the first die 612 in the first semiconductor structure 601 and the second insulation layer 621 in the second semiconductor structure 602 may be brought into contact with each other, and the first semiconductor structure 601 and the second semiconductor structure 602 may be connected by using a “bonding technique”. In an example, in the case that the fabrication method 500 comprises forming the second filling structure 624, during a process in which the first semiconductor structure 601 and the second semiconductor structure 602 are in contact with each other, the first die 612 in the first semiconductor structure 601 and the second filling structure 624 may be also brought into contact with each other.

In some implementations, the second die 622 may be connected to a side of the third insulation layer 631 facing away from the third die 632. For example, the second die 622 in the second semiconductor structure 602 and the third insulation layer 631 in the third semiconductor structure 603 may be brought into contact with each other, and the second semiconductor structure 602 and the third semiconductor structure 603 may be connected by using the “bonding technique”.

In some implementations, the third die 632 may be connected to a side of the fourth insulation layer 641 facing away from the fourth die 642. For example, the third die 632 in the third semiconductor structure 603 and the fourth insulation layer 641 in the fourth semiconductor structure 604 may be brought into contact with each other, and the third semiconductor structure 603 and the fourth semiconductor structure 604 may be connected by using the “bonding technique”.

### S540

FIG. 6D shows an intermediate structure 600d after forming an initial second contact hole 654′. FIG. 6E shows an intermediate structure 600e after forming a first contact hole 653 and a second contact hole 654. FIG. 6F shows a package structure 600 after forming a first contact structure T1 and a second contact structure T2.

As shown in FIGS. 6D to 6F, the first contact structure T1 extending through the first insulation layer 611 along the direction D1 may be formed, and the second contact structure T2 extending through the first filling structure 614, the first die 612 and the second insulation layer 621 along the direction D1 may be also formed, by using an etching (e.g., dry etching and/or wet etching) process and a thin film deposition process such as CVD, PVD, ALD or any combination thereof. For example, the process of forming the first contact structure T1 and the second contact structure T2 includes a Bosch process.

In some implementations, as shown in FIG. 6D, the initial second contact hole 654′ extending through the first filling structure 614, the first dielectric layer 617 and the first die 612 until reaching the second insulation layer 621 may be formed by using an etching (e.g., dry etching) process. When a material of the first filling structure 614 and a substrate material of the first die 612 both include silicon and a material of the second insulation layer 621 includes silicon oxide, the second insulation layer 621 may serve as a stop layer for forming the initial second contact hole 654′.

In some implementations, with continued reference to FIG. 6D, an initial third contact hole 655′ extending through the first filling structure 614, the first dielectric layer 617, the first die 612, the second filling structure 624 and the second dielectric layer 627 until reaching the third insulation layer 631 may be formed by using an etching (e.g., dry etching) process.

In some implementations, with continued reference to FIG. 6D, an initial fourth contact hole 656′ extending through the first filling structure 614, the first dielectric layer 617, the first die 612, the second filling structure 624, the second dielectric layer 627, the third die 632 and the third insulation layer 631 may be formed by using an etching (e.g., dry etching) process.

In some implementations, the initial second contact hole 654′, the initial third contact hole 655′ and the initial fourth contact hole 656′ may be formed in the same etching process to improve the production efficiency and save the production cost.

In some implementations, as shown in FIGS. 6D and 6E, the initial second contact hole 654′ may be deepened until reaching the second routing layer 623 by using an etching (e.g., dry etching) process to form the second contact hole 654, and the first contact hole 653 extending through the first insulation layer 611 may be formed by using an etching (e.g., dry etching) process. For example, the first routing layer 613 and the second routing layer 623 may serve as stop layers for forming the first contact hole 653 and the second contact hole 654, respectively.

In some implementations, with continued reference to FIGS. 6D and 6E, during the process of deepening the initial second contact hole 654′ until reaching the second routing layer 623 to form the second contact hole 654, the initial second contact hole 654′ further extends through the second insulation layer 621. For example, deepening the initial second contact hole 654′ and forming the first contact hole 653 may be performed in the same etching process.

In some implementations, with continued reference to FIGS. 6D and 6E, during the process of deepening the initial second contact hole 654′ until reaching the second routing layer 623 to form the second contact hole 654, deepening the initial third contact hole 655′ and deepening the initial fourth contact hole 656′ and separately forming the third contact hole 655 and the fourth contact hole 656 may be performed in the same etching process. The initial third contact hole 655′ and the initial fourth contact hole 656′ are deepened, such that the initial third contact hole 655′ and the initial fourth contact hole 656′ further extend through the third insulation layer 631 and the fourth insulation layer 641, respectively.

In some implementations, as shown in FIGS. 6E and 6F, the first contact structure T1 may be formed in the first contact hole 653, and the second contact structure T2 may be formed in the second contact hole 654, by using a thin film deposition process such as CVD, PVD, ALD or any combination thereof. For example, the first contact structure T1 and the second contact structure T2 may be formed in the same thin film deposition process.

In some implementations, with continued reference to FIGS. 6E and 6F, a first insulating isolation layer 116 may be formed on a sidewall of the first contact hole 653 (with reference to FIG. 1B), and a first conductive body 115 may be formed on an inner side of the first insulating isolation layer 116 (with reference to FIG. 1B), by using a thin film deposition process such as CVD, PVD, ALD or any combination thereof. The first insulating isolation layer 116 and the first conductive body 115 may serve as the first contact structure T1. A second insulating isolation layer 126 may be formed on a sidewall of the second contact hole 654 (with reference to FIG. 1B), and a second conductive body 125 may be formed on an inner side of the second insulating isolation layer 126 (with reference to FIG. 1B), by using a thin film deposition process such as CVD, PVD, ALD or any combination thereof. The second insulating isolation layer 126 and the second conductive body 125 may serve as the second contact structure T2.

In some implementations, with continued reference to FIGS. 6E and 6F, a third insulating isolation layer 136 may be formed on a sidewall of the third contact hole 655 (with reference to FIG. 1B), and a third conductive body 135 may be formed on an inner side of the third insulating isolation layer 136 (with reference to FIG. 1B), by using a thin film deposition process such as CVD, PVD, ALD or any combination thereof. The third insulating isolation layer 136 and the third conductive body 135 may serve as a third contact structure T3. A fourth insulating isolation layer 146 may be formed on a sidewall of the fourth contact hole 656 (with reference to FIG. 1B), and a fourth conductive body 145 may be formed on an inner side of the fourth insulating isolation layer 146 (with reference to FIG. 1B), by using a thin film deposition process such as CVD, PVD, ALD or any combination thereof. The fourth insulating isolation layer 146 and the fourth conductive body 145 may serve as a fourth contact structure T4.

In some implementations, the insulating isolation layers in the first contact structure T1 to the fourth contact structure T4 may be formed in the same thin film deposition process, and the conductive bodies in the first contact structure T1 to the fourth contact structure T4 may be formed in another thin film deposition process.

In some implementations, as shown in FIG. 6F, the fabrication method 500 may further comprise an operation of connecting the first contact structure T1, the second contact structure T2, the third contact structure T3 and the fourth contact structure T4 with the circuit board 651 through a connection structure 652 (e.g., a solder ball).

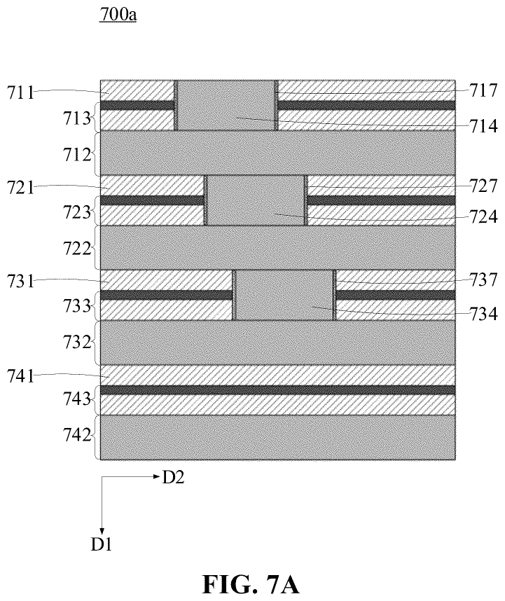

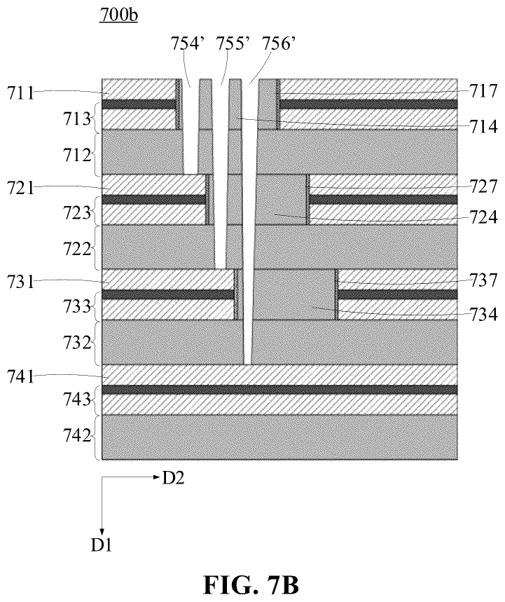

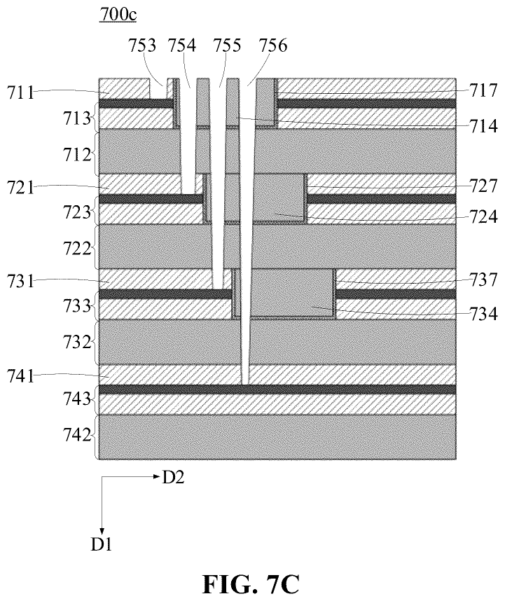

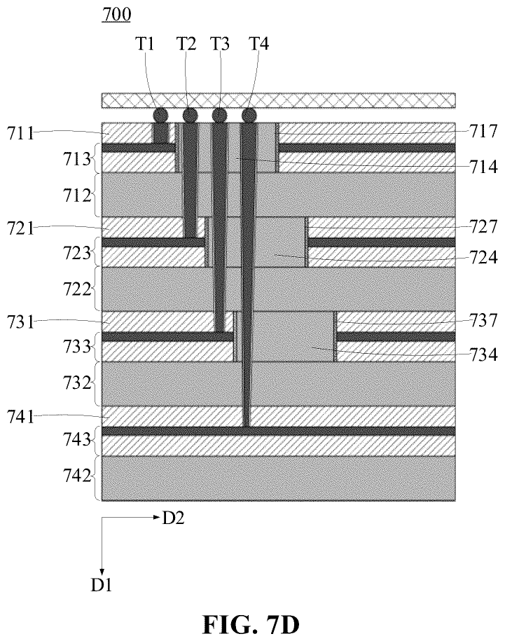

FIGS. 7A to 7D are schematic cross-sectional views of a package structure provided by another example of the present application during a fabrication process. For example, the package structure 200 shown in FIG. 2 are formed in FIGS. 7A to 7D. The fabrication method 500 comprising operations S510 to S540 are illustrated below as an example with reference to FIGS. 7A to 7D. For the purpose of concise description, the same contents as the previous example will be no longer described in the present example.

### S510

FIG. 7A shows an intermediate structure 700a after forming a first insulation layer 711 on a side of a first die 712, forming a second insulation layer 721 on a side of a second die 722, and connecting the first die 712 to a side of the second insulation layer 721 facing away from the second die 722.

As shown in FIG. 7A, the first insulation layer 711 is formed on a side of the first die 712, and a first filling structure 714 extending through the first insulation layer 711 along a direction D1 is formed.

In some implementations, a first routing layer 713 may be formed between the first die 712 and the first insulation layer 711.

In some implementations, a first opening (not shown) extending through the first insulation layer 711 along the direction D1 may be formed by an etching (e.g., dry etching and/or wet etching) process. In an example, in the case that the first routing layer 713 is formed, the first opening further extends through the first routing layer 713 and terminates, e.g., at a surface of the first die 712. Next, a first dielectric layer 717 may be formed on a sidewall of the first opening by using a thin film deposition process such as CVD, PVD, ALD or any combination thereof. Subsequently, the first filling structure 714 is formed in the first opening where the first dielectric layer 717 is formed, by using a thin film deposition process such as CVD, PVD, ALD or any combination thereof. The first filling structure 714 is in contact with the first die 712.

### S520

With continued reference to FIG. 7A, a second insulation layer 721 is formed on a side of the second die 722.

In some implementations, a second routing layer 723 may be formed between the second die 722 and the second insulation layer 721.

In some implementations, a second filling structure 724 extending through the second insulation layer 721 and the second routing layer 723 along the direction D1 may be formed. For example, a second opening (not shown) extending through the second insulation layer 721 and the second routing layer 723 along the direction D1 may be first formed, and then a second dielectric layer 727 is formed on a sidewall of the second opening. The second filling structure 724 is then formed in the second opening where the second dielectric layer 727 is formed. The second filling structure 724 is in contact with the second die 722.

In some implementations, the fabrication method 500 may further comprise: sequentially forming a third routing layer 733 and a third insulation layer 731 on a side of a third die 732; forming a third opening (not shown) extending through the third insulation layer 731 and the third routing layer 733 and terminating at the third die 732; and forming a third dielectric layer 737 on an inner wall of the third opening and forming a third filling structure 734 on an inner side of the third dielectric layer 737. The third filling structure 734 is in contact with the third die 732.

In some implementations, the fabrication method 500 may further comprise: sequentially forming a fourth routing layer 743 and a fourth insulation layer 741 on a side of a fourth die 742.

### S530

With continued reference to FIG. 7A, the first die 712 may be connected to a side of the second insulation layer 721 facing away from the second die 722.

In some implementations, the second die 722 may be connected to a side of the third insulation layer 731 facing away from the third die 732.

In some implementations, the third die 732 may be connected to a side of the fourth insulation layer 741 facing away from the fourth die 742.

### S540

FIG. 7B shows an intermediate structure 700b after forming an initial second contact hole 754′. FIG. 7C shows an intermediate structure 700c after forming a first contact hole 753 and a second contact hole 754. FIG. 7D shows a package structure 700 after forming a first contact structure T1 and a second contact structure T2.

As shown in FIGS. 7B to 7D, the first contact structure T1 extending through the first insulation layer 711 along the direction D1 may be formed, and the second contact structure T2 extending through the first filling structure 714, the first die 712 and the second insulation layer 721 along the direction D1 may be formed. For example, the process of forming the first contact structure T1 and the second contact structure T2 includes a Bosch process.

In some implementations, as shown in FIG. 7B, the initial second contact hole 754′ extending through the first filling structure 714 and the first die 712 until reaching the second insulation layer 721 may be formed by using an etching (e.g., dry etching) process. When a material of the first filling structure 714 and a substrate material of the first die 712 include silicon and a material of the second insulation layer 721 includes silicon oxide, the second insulation layer 721 may serve as a stop layer for forming the initial second contact hole 754′. Moreover, the first dielectric layer 717 is formed on a sidewall of the first filling structure 714 rather than at bottom of the first filling structure 714, which is conducive to reducing the process difficulty of forming the initial second contact hole 754′.

In some implementations, with continued reference to FIG. 7B, an initial third contact hole 755′ extending through the first filling structure 714, the first die 712, the second filling structure 724 and the second die 722 until reaching the third insulation layer 731 may be formed by using an etching (e.g., dry etching) process. Similarly, the second dielectric layer 727 is formed on a sidewall of the second filling structure 724 rather than at bottom of the second filling structure 724, which is conducive to reducing the process difficulty of forming the initial third contact hole 755′.

In some implementations, with continued reference to FIG. 7B, an initial fourth contact hole 756′ extending through the first filling structure 714, the first die 712, the second filling structure 724, the second die 722, the third filling structure 734 and the third die 732 until reaching the fourth insulation layer 741 may be formed by using an etching (e.g., dry etching) process. The third dielectric layer 737 is formed on a sidewall of the third filling structure 734 rather than at bottom of the third filling structure 734, which is conducive to reducing the process difficulty of forming the initial fourth contact hole 756′.

In some implementations, as shown in FIGS. 7B and 7C, the initial second contact hole 754′ may be deepened until reaching the second routing layer 723 to form the second contact hole 754, and the first contact hole 753 extending through the first insulation layer 711 may be formed. In an example, the initial third contact hole 755′ may be deepened until reaching the third routing layer 733 to form a third contact hole 755, and the initial fourth contact hole 756′ may be deepened until reaching the fourth routing layer 743 to form a fourth contact hole 756.

In some implementations, as shown in FIGS. 7C and 7D, the first contact structure T1 may be formed in the first contact hole 753, and the second contact structure T2 may be formed in the second contact hole 754. In an example, during that process, a third contact structure T3 may be formed in the third contact hole 755, and a fourth contact structure T4 may be formed in the fourth contact hole 756.

Some examples of the present application further provide a semiconductor structure. For example, the semiconductor structure may be the first semiconductor structure 101 in the package structure 100 shown in FIGS. 1A and 1B.

As shown in FIGS. 1A and 1B, the first semiconductor structure 101 comprises the first die 112, the first routing layer 113, the first insulation layer 111 and the first contact structure T1. The first routing layer 113 is located on a surface of the first die 112. The first insulation layer 111 is located on a surface of the first routing layer 113. The first contact structure T1 extends through the first insulation layer 111 until reaching the first routing layer 113.

In some implementations, a surface of the first die 112 facing the first routing layer 113 has a plurality of first pad structures (not shown), and the first routing layer 113 comprises a first insulation material layer 1133, and at least one layer of first via structure 1132 and at least one layer of first interconnection line 1131 that are located in the first insulation material layer 1133, wherein the first pad structures is in contact with the first via structure 1132, and the first contact structure T1 is in contact with the first interconnection line 1131.

In some implementations, the first contact structure T1 comprises a first conductive body 115 and a first insulating isolation layer 116. The first conductive body 115 is in contact with the first interconnection line 1131. The first insulating isolation layer 116 surrounds an outer side of the first conductive body 115.

In some implementations, materials of the first conductive body 115 and the first interconnection line 1131 both comprise tungsten.

The above description is merely an illustration of implementations of the present application and technical principles applied. Those skilled in the art should understand that, the protection scope of the present application is not limited to the technical solutions formed by a specific combination of the above technical features, but also should encompass other technical solutions formed by any combination of the above technical features or equivalent features thereof without departing from the technical conception, for example, technical solutions formed by replacing the above features with the technical features having similar functions as disclosed (but not limited thereto) in the present application.

What is claimed is:

1. A package structure, comprising a first insulation layer, a first die, a second insulation layer, and a second die in sequence along a first direction, and further comprising:
a first filling structure extending through the first insulation layer along the first direction;
a first contact structure extending through the first insulation layer along the first direction; and
a second contact structure extending through the first filling structure, the first die, and the second insulation layer along the first direction.

2. The package structure of claim 1, further comprising:
a first routing layer between the first insulation layer and the first die; and
a second routing layer between the second insulation layer and the second die,
wherein the first filling structure extends into the first routing layer.

3. The package structure of claim 2, wherein the first routing layer and the second routing layer both comprise an insulation material layer, and at least one layer of via structure and at least one layer of interconnection line that are located in the insulation material layer.

4. The package structure of claim 2, further comprising:
a second filling structure extending through the second insulation layer along the first direction and extending into the second routing layer.

5. The package structure of claim 4, wherein materials of the first filling structure and the second filling structure both comprise silicon.

6. The package structure of claim 5, wherein a sidewall of the first filling structure has a spacing distance from a sidewall of the second filling structure in a second direction, wherein the second direction intersects the first direction.

7. The package structure of claim 2, wherein the first routing layer is in contact with the first insulation layer and the first die separately, and the first insulation layer, the first routing layer, and the first die serve as a first semiconductor structure;
the second routing layer is in contact with the second insulation layer and the second die separately, and the second insulation layer, the second routing layer, and the second die serve as a second semiconductor structure,
wherein the second semiconductor structure is connected with the first semiconductor structure by bonding.

8. The package structure of claim 7, wherein on a side of the second die facing away from the first insulation layer, the package structure further comprises a third insulation layer, a third routing layer, and a third die in sequence along the first direction.

9. The package structure of claim 8, wherein the third routing layer is in contact with the third insulation layer and the third die separately, and the third insulation layer, the third routing layer, and the third die serve as a third semiconductor structure connected with the second semiconductor structure by bonding, wherein at least one of the third semiconductor structures is arranged along the first direction, and adjacent ones of the third semiconductor structures are connected by bonding.

10. The package structure of claim 1, further comprising:
a first dielectric layer located on a sidewall of the first filling structure,
wherein the first filling structure is in contact with the first die.

11. The package structure of claim 1, further comprising:
a first dielectric layer that is located on a sidewall of the first filling structure and that is on a surface of the first filling structure facing the first die and that is in contact with the first die.

12. The package structure of claim 1, wherein the first die is further in contact with the second insulation layer.

13. The package structure of claim 1, wherein in a plane perpendicular to the first direction, a size of the first contact structure is 50-300 nm, and a size of the second contact structure is 50-300 nm.

14. The package structure of claim 1, wherein in a plane perpendicular to the first direction, a size of the first contact structure is smaller than a size of the second contact structure.

15. The package structure of claim 1, wherein the first filling structure is located at a middle portion of the first insulation layer or located at a periphery of the first insulation layer.

16. The package structure of claim 1, wherein the first die comprises a memory array structure and a peripheral circuit structure along the first direction, and the memory array structure and the peripheral circuit structure are connected by bonding.

17. A semiconductor structure, comprising:
a first die;
a first routing layer on a surface of the first die;
a first insulation layer on a surface of the first routing layer; and
a first contact structure extending through the first insulation layer until reaching the first routing layer.

18. The semiconductor structure of claim 17, wherein a surface of the first die facing the first routing layer has a plurality of first pad structures; and the first routing layer comprises a first insulation material layer, and at least one layer of first via structure and at least one layer of first interconnection line that are located in the first insulation material layer,
wherein the first pad structures are in contact with the first via structure, and the first contact structure is in contact with the first interconnection line.

19. The semiconductor structure of claim 18, wherein the first contact structure comprises a first conductive body and a first insulating isolation layer, the first conductive body is in contact with the first interconnection line, and the first insulating isolation layer surrounds an outer side of the first conductive body.

20. A fabrication method of a package structure, comprising:
forming a first insulation layer on a side of a first die, and forming a first filling structure extending through the first insulation layer along a first direction;
forming a second insulation layer on a side of a second die;
connecting the first die to a side of the second insulation layer facing away from the second die; and
forming a first contact structure extending through the first insulation layer along the first direction and forming a second contact structure extending through the first filling structure, the first die and the second insulation layer along the first direction,
wherein the first direction is a stacking direction of the first die and the second die.
